(19) United States
(12) Patent Application Publication
(10) Pub. No.: US 2024/0357910 A1
(43) Pub. Date: Oct. 24, 2024

(54) LIGHT-EMITTING APPARATUS, DISPLAY APPARATUS, IMAGING APPARATUS, ELECTRONIC APPARATUS, ILLUMINATION APPARATUS, AND MOVABLE BODY

(71) Applicant: CANON KABUSHIKI KAISHA, Tokyo (JP)

(72) Inventors: NORIFUMI KAJIMOTO, Kanagawa (JP); HIROAKI SANO, Tokyo (JP); YOJIRO MATSUDA, Kanagawa (JP)

(21) Appl. No.: 18/762,425

(22) Filed: Jul. 2, 2024

Related U.S. Application Data
(63) Continuation of application No. PCT/JP2022/000067, filed on May 1, 2022.

(51) Int. Cl. H10K 59/80; H10K 59/35

(52) U.S. Cl. CPC H10K 59/879; H10K 59/35

(57) ABSTRACT

A light-emitting apparatus includes a substrate having a main surface, a first light-emitting element and a second light-emitting element, a first lens for and, a second lens for the second light-emitting element, wherein the first and the second light-emitting element includes a lower electrode, an upper electrode, a light-emitting layer, and an insulating layer covering an edge of the lower electrode to define a light-emitting region, wherein, in a direction parallel to the main surface, a distance between a midpoint of the light-emitting region of the second light-emitting element and an apex of the second lens is larger than a distance between a midpoint of the light-emitting region of the first light-emitting element and an apex of the first lens, and wherein the light-emitting region of the second light-emitting element is larger than the light-emitting region of the first light-emitting element.

### CROSS-REFERENCE TO RELATED APPLICATIONS

This application is a Continuation of International Patent Application No. PCT/JP2022/000067, filed Jan. 5, 2022, which is hereby incorporated by reference herein in its entirety.

### BACKGROUND OF THE INVENTION

### Field of the Invention

The present invention relates to a light-emitting apparatus including an optical member such as a microlens. The present invention also relates to a display apparatus, an electronic apparatus, an illumination apparatus, and a movable body including the light-emitting apparatus.

### Background Art

An organic light-emitting element is an element including a first electrode, a second electrode, and an organic compound layer disposed between the first and the second electrodes. The organic light-emitting element is a light-emitting device that emits light when carriers are injected from the first and the second electrodes. Since an organic light-emitting element is a light-weight flexible device, display apparatuses including an organic light-emitting element have attracted attention in recent years. A method for using an organic white-light-emitting element and color filters has been used to increase the definition of such a display apparatus (hereinafter this method is referred to as a white+CF method). In the white+CF method, because an organic layer is formed on the entire surface of a substrate, the definition is comparatively easily increased by reducing the pixel size and pixel distance in comparison with a case using a method that uses metal masks to form an organic layer for each color.

Japanese Patent Application Laid-Open No. 2017-017013 (PTL 1) discusses a display apparatus including an organic light emitting diode (OLED) and an out-coupling component, and discusses a positional relationship between the out-coupling component and an OLED light-emitting region.

Japanese Patent Application Laid-Open No. 2020-004868 (PTL 2) discusses a light-emitting device including a microlens array and a light-emitting element group, and discusses a technique for varying the distance between the light emission center axis of a light-emitting element and the center axis of a lens.

### CITATION LIST

### Patent Literature

PTL 1: Japanese Patent Application Laid-Open No. 2017-017013
PTL 2: Japanese Patent Application Laid-Open No. 2020-004868

PTL 1 discusses a positional relationship such as the distance between a light-emitting element and a microlens to increase the strength in the front direction. PTL 2 discusses a technique for varying the distance between the center axis of a light-emitting element and the center axis of a microlens to uniform a light quantity in each light-emitting direction.

However, in consideration of the power consumption and the display quality of the light-emitting device, the above-described documents do not discuss a technique for varying the size of the light-emitting region.

### SUMMARY OF THE INVENTION

The present invention has been embodied in view of the above-described issue, and is directed to providing a display apparatus capable of stabilizing the display quality regardless of the user's line-of-sight position while the light usage efficiency is improved by using an optical member such as a microlense and the power consumption is reduced.

According to an aspect of the present invention, a light-emitting apparatus includes a substrate having a main surface, a first light-emitting element and a second light-emitting element disposed in the main surface, a first lens configured to receive incident light emitted from the first light-emitting element, and, a second lens configured to receive incident light emitted from the second light-emitting element, wherein the first light-emitting element and the second light-emitting element includes a lower electrode, an upper electrode, a light-emitting layer disposed between the lower electrode and the upper electrode, and an insulating layer covering an edge of the lower electrode to define a light-emitting region, wherein, in a direction parallel to the main surface, a distance between a midpoint of the light-emitting region of the second light-emitting element and an apex of the second lens is larger than a distance between a midpoint of the light-emitting region of the first light-emitting element and an apex of the first lens, and wherein the light-emitting region of the second light-emitting element is larger than the light-emitting region of the first light-emitting element.

Further features of the present invention will become apparent from the following description of exemplary embodiments with reference to the attached drawings.

### BRIEF DESCRIPTION OF THE DRAWINGS

FIG. 1A is a cross-sectional view illustrating an example of a first light-emitting element included in a light-emitting apparatus according to an exemplary embodiment of the present invention.

FIG. 1B is a plan view illustrating the first light-emitting element in FIG. 1A.

FIG. 2A is a cross-sectional view illustrating an example of a second light-emitting element included in the light-emitting apparatus according to an exemplary embodiment of the present invention.

FIG. 2B is a plan view illustrating the second light-emitting element in FIG. 2A.

FIG. 3 is a cross-sectional view illustrating a comparative example.

FIG. 4A is a plan view illustrating the light-emitting apparatus according to an exemplary embodiment of the present invention.

FIG. 4B is a cross-sectional view taken along the A-A′ line of FIG. 4A.

FIG. 5 is a cross-sectional view illustrating an example of a light-emitting apparatus according to an exemplary embodiment of the present invention.

FIG. 6 is a cross-sectional view illustrating an example of an effect of the present invention.

FIG. 7 schematically illustrates an example of a display apparatus according to an exemplary embodiment of the present invention.

FIG. 8A schematically illustrates an example of an imaging apparatus according to an exemplary embodiment of the present invention.

FIG. 8B schematically illustrates an example of an electronic apparatus according to an exemplary embodiment of the present invention.

FIG. 9A schematically illustrates an example of a display apparatus according to an exemplary embodiment of the present invention.

FIG. 9B schematically illustrates an example of a foldable display apparatus.

FIG. 10A schematically illustrates an example of an illumination apparatus according to an exemplary embodiment of the present invention.

FIG. 10B schematically illustrates an example of an automobile with a vehicle lighting according to an exemplary embodiment of the present invention.

FIG. 11A illustrates an example of smart glasses according to an exemplary embodiment of the present invention.

FIG. 11B illustrates another example of smart glasses according to an exemplary embodiment of the present invention.

FIG. 12A is a conceptual diagram illustrating a relationship between a display apparatus used together with an optical system and an observer when the observer's line-of-sight is at the center of a display panel.

FIG. 12B is a conceptual diagram illustrating a relation between the display apparatus used together with the optical system and the observer when the observer's line-of-sight is at an edge of the display panel.

FIG. 13A illustrates a relationship between the panel viewing angle and the radiation angle on the display panel under general view and gazing conditions.

FIG. 13B illustrates a relationship between the panel viewing angle and the difference between a maximum value and a minimum value of the radiation angle under general view and gazing conditions.

### DESCRIPTION OF THE EMBODIMENTS

A light-emitting apparatus includes a substrate having a main surface, a first light-emitting element and a second light-emitting element disposed in the main surface, a first lens configured to receive incident light emitted from the first light-emitting element, and, a second lens configured to receive incident light emitted from the second light-emitting element, wherein the first light-emitting element and the second light-emitting element includes a lower electrode, an upper electrode, a light-emitting layer disposed between the lower electrode and the upper electrode, and an insulating layer covering an edge of the lower electrode to define a light-emitting region, wherein, in a direction parallel to the main surface, a distance between a midpoint of the light-emitting region of the second light-emitting element and an apex of the second lens is larger than a distance between a midpoint of the light-emitting region of the first light-emitting element and an apex of the first lens, and wherein the light-emitting region of the second light-emitting element is larger than the light-emitting region of the first light-emitting element.

The second light-emitting element may be a light-emitting element that emits light toward the wide angle of the display apparatus. In the second light-emitting element, optical elements are disposed in a deviated way more than optical elements in the first light-emitting element to emit wide-angle light. More specifically, in a cross-section including the lower electrode and the first and the second optical members, the distance between the midpoint of the light-emitting region of the second light-emitting element and the apex of the second lens is larger than the distance between the midpoint of the light-emitting region of the first light-emitting element and the apex of the first lens.

In this case, the range of the radiation angle required by the second light-emitting element to stabilize the display quality regardless of the user's line-of-sight position is larger than that required by the first light-emitting element. This is because the range of the radiation angle increases with an increase in light-emitting region since the radiation angle is determined by the positional relationship between the optical members and a micro light source in the light-emitting region.

To stabilize the display quality regardless of the user's line-of-sight position, in the second light-emitting element, the light-emitting region of the second light-emitting element is larger than the light-emitting region of the first light-emitting element. With the large light-emitting region, the radiation intensity with respect to the input current decreases but the display quality during the user's eye rotation is stabilized in the wide range of the radiation angle.

According to the present specification, optical members include members for concentrating incident light and members for refracting incident light, such as lenses and prisms. The light-emitting layer may be composed of an organic compound or an inorganic compound.

Exemplary embodiments will be described in detail below with reference to the accompanying drawings. The following exemplary embodiments do not limit the present invention. Although a plurality of configurations is described in the exemplary embodiments, not all of the plurality of configurations is indispensable to the present invention, and the plurality of configurations may be arbitrarily combined. In the drawings, identical or similar components are assigned the same reference numerals, and duplicated descriptions thereof will be omitted.

For example, in the white+CF method, color filters may be red-, green-, and blue-light-transmitting color filters. An organic electroluminescence (EL) light-emitting apparatus enables full color display through the additive color mixing with these sub pixels. Although exemplary embodiments will be described below centering on three different color filters transmitting the three primary colors, the present invention is not limited thereto.

According to the present specification, lenses may be disposed on the light extraction side of the light-emitting apparatus, and the convexity direction of lenses may refer to the light extraction side. In a case where the light-emitting apparatus emits light from both the upper and the lower electrodes of the light-emitting element, directions of both electrodes can be referred to as a light extraction side. Applicable microlenses shapes include spherical lenses, aspherical lenses, and digital microlens.

Applicable planar arrays include a stripe array, a square array, a delta array, and a Bayer array. The delta array is particularly desirable since this array enables microlens (ML) having shapes for high lens power or a high light extraction efficiency to be disposed with high accuracy. Also, disposing main pixels in a matrix leads to the achievement of a light-emitting apparatus having a large number of pixels.

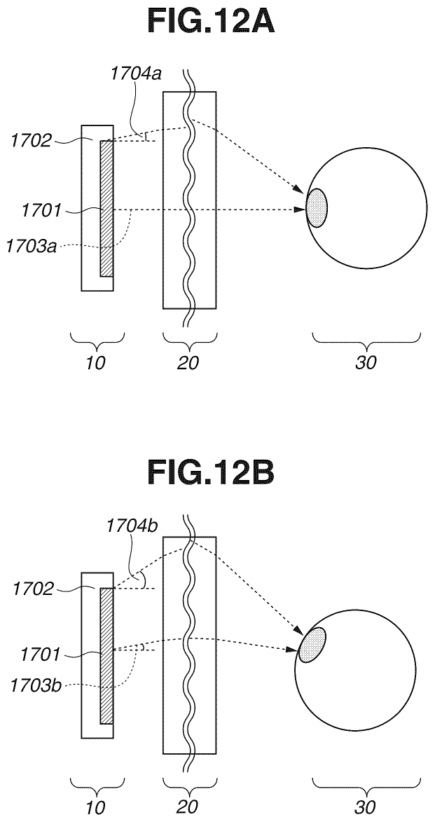

A head mount display is an example of an application of an organic light-emitting element together with an optical system. FIGS. 12A and 12B schematically illustrate light paths from an organic light-emitting apparatus 10 to an eyeball 30 of the user. FIG. 12A illustrates a case where the user's line-of-sight is at a panel center 1701, which is referred to as a general view condition. At the general view condition, a panel viewing angle 1703a and a radiation angle 1704a are low. Since the light from a panel end 1702 is visually recognized as a peripheral visual field, the sensitivity to a luminance drop or color shift is low. However, since the user uses the head mount display for a prolonged period of time, it is desirable that the display performance under the general view condition be maintained. FIG. 12B illustrates a case where the user turns the eyeball 30 to move the gazing position, which is referred to as a gazing condition. FIG. 12B illustrates an example case where the user gazes the panel end 1702. At the gazing condition, a panel viewing angle 1703b and a radiation angle 1704b are high. Even though the user does not gaze the panel end 1702 for a prolonged period of time, since the user perceives the panel end 1702 at the central visual field, the sensitivity to a luminance drop or color shift is high. As described above, it is desirable that a head mount display be designed to maintain the display performance under both the general view and the gazing conditions.

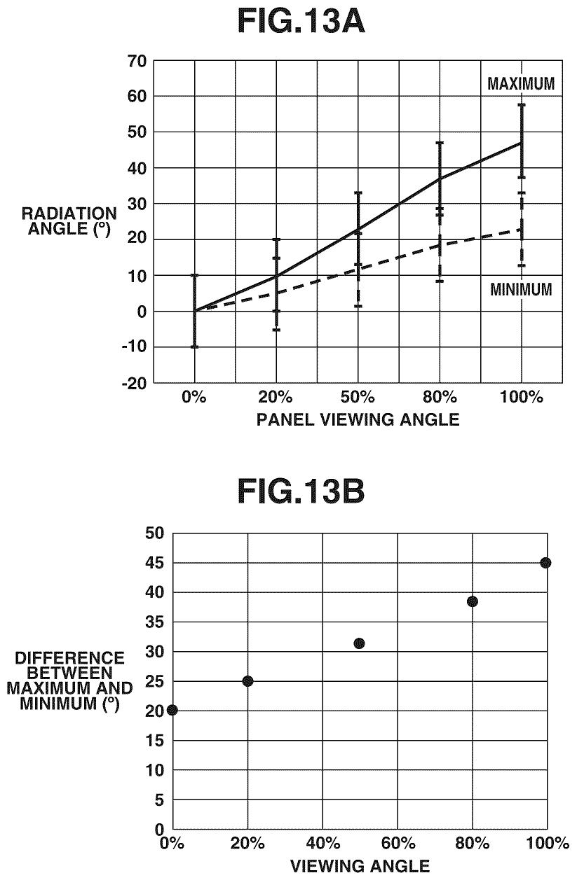

FIG. 13A illustrates a relationship between the panel viewing angle and the radiation angle of light factoring in the general view and the gazing conditions. A panel viewing angle of 0% at the horizontal axis in FIG. 13A corresponds to the panel center 1701 in FIG. 12A, and a panel viewing angle of 100% in FIG. 13A corresponds to the panel end 1702 in FIG. 12A. The solid and the broken lines in FIG. 13A correspond to the radiation angles under the gazing and the general view conditions, respectively. The error bars represent the positional deviation of the head mount display relative to the eyeball 30 of the user. Although the absolute value of the vertical axis in FIG. 13A may vary according to the distance between the organic light-emitting apparatus 10 and the eyeball 30 or field of view (FOV), the relative relationship between them remains unchanged.

FIG. 13A illustrates that, under both the general view and the gazing conditions, the required radiation angle increases with an increase in panel viewing angle. The increase in the radiation angle under the gazing condition is larger than the increase in the radiation angle under the general view condition by the amount of the user's eye rotation. This tendency is noticeable with an increase in panel viewing angle. FIG. 13B illustrates a relationship between the difference between the minimum radiation angle under the general view condition and the maximum radiation angle under the gazing condition, and the panel viewing angle. Referring to FIG. 13B, the difference between the maximum and the minimum angles increases with an increase in panel viewing angle. The present inventors found that, when the light-emitting apparatus is used for a head mount display, a wider radiation angle property is more desirable at the panel edges. According to an aspect of the present invention, the light-emitting apparatus includes a first region in a display region and a second region around the first region. A light-emitting region of each light-emitting element in the second region is set larger than a light-emitting region of each light-emitting element in the first region, which improves the display quality.

A light-emitting element may have a microlens. In a case of a light-emitting element having a microlens, the light-emitting apparatus may have the second light-emitting element in which the distance between the center axis of the light-emitting region and the center axis of the microlens is larger than that in the first light-emitting element in a cross-section perpendicular to the main surface of the substrate. The second light-emitting element may have a light-emitting region larger than a light-emitting region of the first light-emitting element.

The first light-emitting element may have a first electrode smaller than a first electrode of the second light-emitting element. The electrode is configured not to be too large relative to the light-emitting region.

### First Exemplary Embodiment

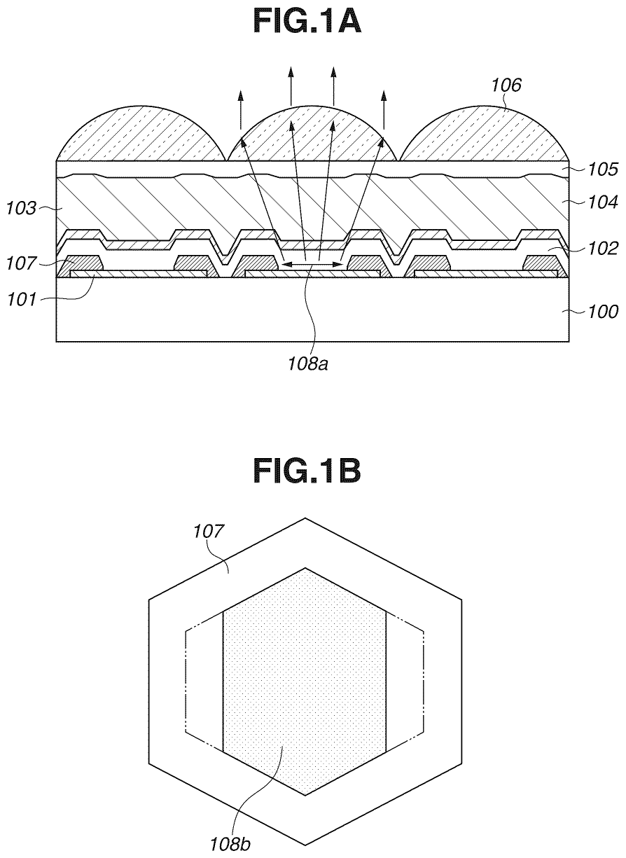

FIGS. 1A and 1B illustrate the first light-emitting element of the light-emitting apparatus according to a first exemplary embodiment of the present invention. FIG. 1A is a cross-sectional view illustrating the first light-emitting element, and FIG. 1B is a plan view illustrating the first light-emitting element illustrated in FIG. 1A.

In FIG. 1A, the light-emitting apparatus includes a lower electrode 101, a function layer 102 including a light-emitting layer, an upper electrode 103, a protective layer 104, a flattening layer 105, a microlens 106, and an insulating layer 107 covering both edges of the lower electrodes 101 which are all disposed on a substrate 100. In the insulating layer 107, a portion in contact with one edge of the lower electrode 101 may be referred to a first insulating layer, and a portion in contact with the other edge of the lower electrode 101 may be referred to as a second insulating layer. The insulating layer 107 is also referred to as a pixel separation film or bank. The cross-sectional view in FIG. 1A is a cross-section perpendicular to the main surface of the substrate. The plan view in FIG. 1B is a plan view viewed in a direction perpendicular to the main surface of the substrate 100. The main surface of the substrate 100 is a surface in which light-emitting elements are disposed. In the surface on which light-emitting elements are disposed, insulating films, such as oxide films, may be disposed between the substrate 100 and the light-emitting elements. In the insulating films, transistors, capacitive elements, and reflecting films may be disposed.

The insulating layer 107 is in contact with an edge of the lower electrode 101 to cover the edge. The portion of the lower electrode 101 not in contact with the insulating layer 107 may be in contact with the function layer 102. The region where the function layer 102 and the lower electrode 101 are in contact with each other is a light-emitting region 108a that emits light when an electric field is applied between the lower electrode 101 and the upper electrode 103.

The light-emitting region may be identified when viewed from the same direction as in FIG. 1B while the region is emitting light during application of an electric field. In FIGS. 1A and 1B, the light-emitting region may be identified by measuring the distance from an edge of the first insulating layer covering the left-hand edge of the lower electrode 101 to an edge of the second insulating layer covering the right-hand edge of the lower electrode 101. The edges of the insulating layer 107 may be contacts between the insulating layer 107 and the lower electrode 101.

In the example illustrated in FIG. 1A, the positional relationship between the microlens 106 and the light-emitting region 108a is optimized. Since the light-emitting region 108a is smaller than a light-emitting region 108b, almost all light components are emitted in the panel front direction. In other words, the range of the panel radiation angle is relatively small.

In FIG. 1B, the light-emitting region 108b is surrounded by the insulating layer 107. While, in the present exemplary embodiment, the light-emitting region 108b is a hexagon, the light-emitting region may be another polygon or a circle. For example, a stripe array in which rectangular red, green, and blue (RGB) light-emitting regions are arranged for light emission is also applicable.

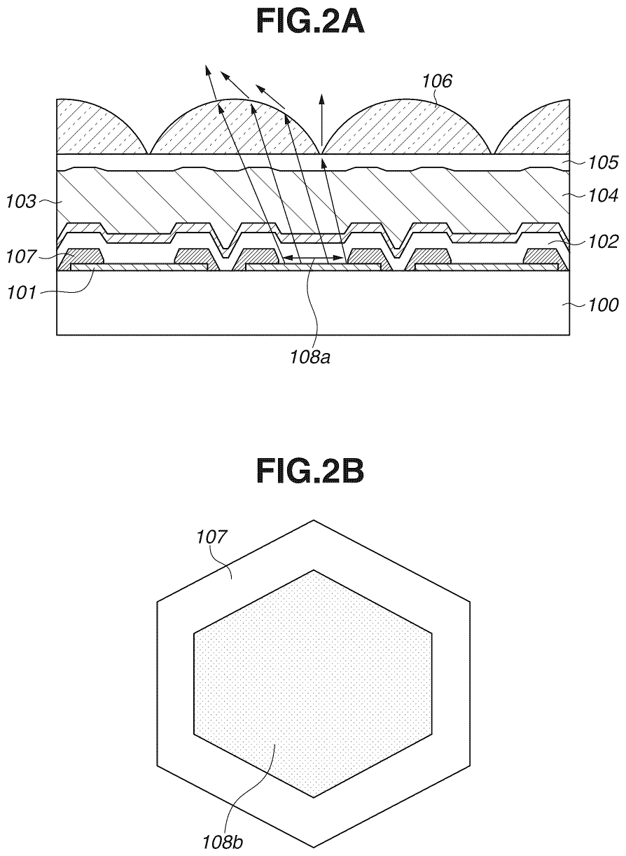

FIGS. 2A and 2B illustrate the second light-emitting element of the light-emitting apparatus according to the present invention. FIG. 2A is a cross-sectional view illustrating the second light-emitting element, and FIG. 2B is a plan view illustrating the second light-emitting element illustrated in FIG. 2A. The cross-sectional view and the plan view are similar to the drawings in FIGS. 1A and 1B, respectively.

The second light-emitting element has a similar configuration to the first light-emitting element. In a direction parallel to the main surface of the substrate 100, the distance between the midpoint of the light-emitting region 108a of the second light-emitting element and the apex of the microlens 106 is larger than the distance between the midpoint of light-emitting region 108a of the first light-emitting element and the apex of the microlens 106. When the position of the microlens 106 of the first light-emitting element is defined as the normal position, the position of the microlens 106 of the second light-emitting element can be considered to be deviated.

In a case of a convex lens, the apex of the microlens 106 is at the farthest position from the main surface of the substrate 100 in a plane perpendicular to the main surface. In a case of a concave lens, the apex of the microlens 106 is at the closest position from the main surface of the substrate in a plane perpendicular to the main surface. The apex of a lens also refers to the center of the lens in a cross-section parallel to the main surface of the substrate.

The light-emitting region 108a of the second light-emitting element is larger than the light-emitting region 108a of the first light-emitting element. More specifically, the light-emitting region 108a in FIG. 2A is longer as a line segment than the light-emitting region 108a in FIG. 1A. In other words, the function layer 102 is in contact with the lower electrode 101 in a larger area.

With the light-emitting region 108b having a larger size, the radiation angle of light having passed through the microlens 106 varies with a position of a point light source existing in the light-emitting region 108b. This means that the range of the panel radiation angle is wide. With the light-emitting region 108b of the second light-emitting element having a larger size in this way, the display quality is stabilized regardless of the user's line-of-sight position.

FIG. 2B illustrates a form of the light-emitting region 108b. According to the present exemplary embodiment, two sides on the right- and left-hand sides of the light-emitting region 108b lie outside the hexagon of the light-emitting region 108b. More specifically, the light-emitting region 108b of the second light-emitting element is a hexagon, and at least one side of the hexagon lies outside the hexagon of the light-emitting region 108a of the first light-emitting element. The two sides among the six sides of the hexagon of the light-emitting region 108b is a pair of sides most separated from each other.

While, in the present exemplary embodiment, in a comparison between the light-emitting region 108a and the light-emitting region 108b, the two sides of the hexagon of the light-emitting region 108a lie inside the hexagon of the light-emitting region 108b, at least one side of a polygon of the light-emitting region 108a may lie inside a polygon of the light-emitting region 108b of the second light-emitting element.

### Comparative Example

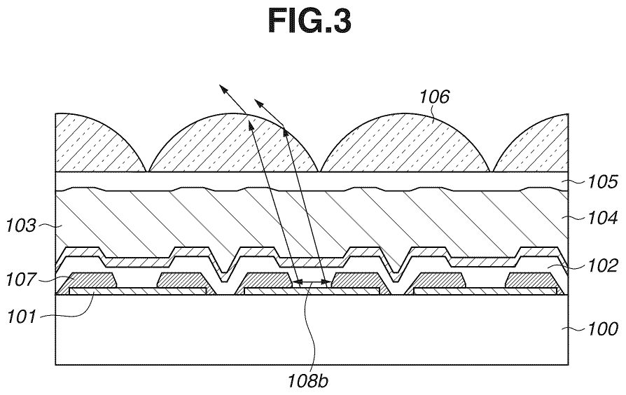

FIG. 3 is a cross-sectional view illustrating a comparative example. According to the comparative example, the positional relationship between the light-emitting region 108b of the second light-emitting element and the optical member is different from the positional relationship between the light-emitting region 108a of the first light-emitting element and the optical member. However, the light-emitting region 108b of the second light-emitting element has the same size as the light-emitting region 108a of the first light-emitting element. The difference between the positional relationship in the second light-emitting element and the positional relationship in the first light-emitting element causes the positional deviation of the optical member. The direction in which the optical members are deviated may be the direction in which the light emitted from the light-emitting layer is to be bent.

The light from the light-emitting region 108b is bent in a direction with a certain angle as illustrated in FIG. 3. Consequently, in the comparative example, a distribution of the radiation angle is smaller than distribution of the radiation angle in the configuration illustrated in FIG. 2A. Due to this reason, the peripheral visual field may be dark, and embodying the comparative example is undesirable for specifications that gives importance to the general view condition.

Thus, with a wide range of the radiation angle by increasing the light-emitting region 108b of the second light-emitting element in size as illustrated in FIG. 2A, the display quality can be stabilized even in a case where the user's line-of-sight changes over a wide range.

The display apparatus using light traveling in a direction oblique to the display surface in the outer circumference region of the display apparatus includes a display unit and an optical system. With such a display apparatus, the user often visually recognizes the display unit via the optical system. In this form of the display apparatus, the first light-emitting element that can concentrate light in the front direction is often disposed in the panel center region. This is because the luminance of the display apparatus is set based on values at the panel center. Preventing the emission of unused light will provide the following effects. For example, if unused light is incident on an optical system 20 in FIGS. 12A and 12B, the unused light becomes stray light, which can degrade the display quality. The above-described exemplary embodiment prevents emission of light not contributing to display, which also has an effect of reducing stray light.

While the present exemplary embodiment has been described above centering on an example of the light-emitting apparatus having macrolenses. In a case of the light-emitting region not largely contributing to the light emission of the display apparatus, the light-emitting region may be reduced in size, and the presence or absence of optical members such as microlenses does not matter.

For example, a light-emitting apparatus may have a first light-emitting region and a second light-emitting region around the first light-emitting region, and a light-emitting element included in the second light-emitting region may be required to have a wide radiation angle property for the light emission of the light-emitting apparatus. In this case, a light-emitting region of the light-emitting element included in the second light-emitting region may be increased in size.

Since the second light-emitting region is around the first light-emitting region, the second light-emitting region includes regions disposed outside the first light-emitting region with respect to the display apparatus. A light-emitting element described with the term “outside” indicates, among a plurality of light-emitting elements on the substrate, a light-emitting element disposed closer to an edge of the substrate than a certain light-emitting element, and the light-emitting element is referred to as an outer light-emitting element. The edge of the substrate in this case is the edge of the substrate closest to the relevant certain light-emitting element.

According to the present exemplary embodiment, the range of the radiation angle of the second light-emitting element is increased, whereby a desirable display quality regardless of the user's line-of-sight position is provided and a low power consumption is also maintained.

### Second Exemplary Embodiment

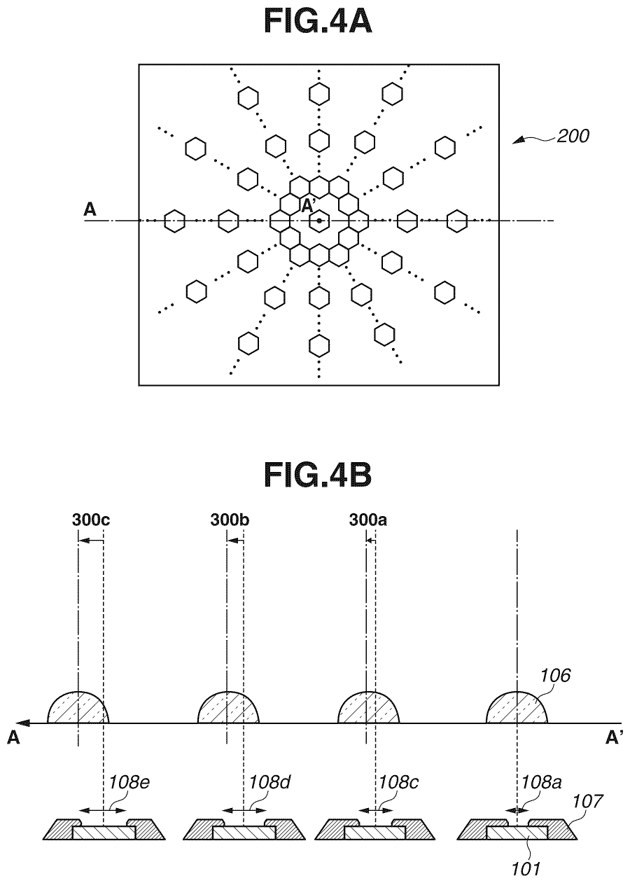

FIGS. 4A and 4B illustrate an example of a light-emitting apparatus according to a second exemplary embodiment of the present invention. FIG. 4A illustrates a light-emitting apparatus in a planar view viewed in a direction perpendicular to the main surface of the substrate, as in FIG. 1B. A display region 200 includes a plurality of light-emitting elements. The positional relationship between the light-emitting region and the microlens 106 will be described below with reference to a center portion A′ and an outer circumference portion A.

FIG. 4B is a partial cross-sectional view illustrating the light-emitting apparatus taken along the A-A′ line of FIG. 4A. In the cross-section, some light-emitting elements are omitted. The positional relationship between the microlens 106 and the light-emitting region changes toward the outer circumference portion A from the center portion A′. More specifically, with reference to the positional relationship between the light-emitting region 108a and the microlens 106 right above the light-emitting region 108a, the positional relationship between a light-emitting region 108c and the microlens 106 right above the light-emitting region 108c is such that the microlens 106 is relatively deviated to the left by an amount 300a as illustrated in FIG. 4B. The light-emitting region 108c is larger than the light-emitting region 108a. Likewise, a light-emitting region 108d is larger than the light-emitting region 108c, and the microlens 106 right above the light-emitting region 108d is relatively deviated by an amount 300b. Further, a light-emitting region 108e is larger than the light-emitting region 108d, and the microlens 106 right above the light-emitting region 108e is relatively deviated by an amount 300c.

According to the present exemplary embodiment, the first light-emitting element has the light-emitting region 108a, the second light-emitting element has the light-emitting region 108c, a third light-emitting element has the light-emitting region 108d, and a fourth light-emitting element has the light-emitting region 108e.

In FIG. 4A, for example, light-emitting elements closer to the outer circumference portion A than to the center portion A′ are outer light-emitting elements. Light-emitting elements farther from the center portion A′ can be considered to be outer light-emitting elements.

The deviation amount of the microlens 106 increases toward the outer circumference portion A from the center portion A′ in the display region in this way.

The variation of the deviation may also be implemented in such manner that the deviation increases toward the outer circumference portion A. This means that the difference between the deviation amounts in the light-emitting regions 108e and 108d is larger than the difference between the deviation amounts in the light-emitting regions 108d and 108c. In this case, the deviation amount at the outer circumference portion A does not need to be 0. More specifically, the lens center does not need to be disposed at the center of the display apparatus.

The variation of the deviation amount may decrease toward the outer circumference portion A. This means that the difference between the deviation amounts in the light-emitting regions 108e and 108d is smaller than the difference between the deviation amounts in the light-emitting regions 108d and 108c. Although the variation decreases, the deviation amount in the light-emitting region 108e is larger than that in the light-emitting region 108d. In this case, the deviation amount at the outer circumference portion A does not need to be 0. More specifically, the lens center does not need to be disposed at the center of the display apparatus.

The continuous or gradual increase in the light-emitting region in this way enables providing a light-emitting apparatus having a high display quality.

### Third Exemplary Embodiment

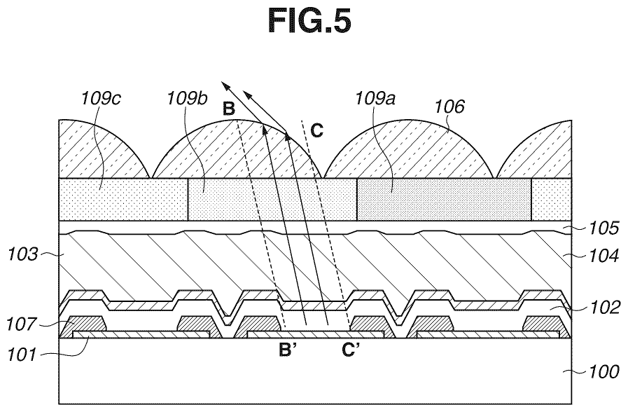

FIG. 5 is a cross-sectional schematic view illustrating a light-emitting apparatus according to a third exemplary embodiment of the present invention. Color filters 109a to 109c are disposed on the flattening layer 105 in addition to the configuration according to the first exemplary embodiment. The color filters 109a to 109c are included in three different sub pixels that can be considered as one main pixel. Since a pixel includes color filters, light passing through the color filter can be considered as light emitted by the light-emitting layer of the relevant pixel. It is desirable that the sub pixels correspond to three different colors (red, green, and blue). Full color display is enabled through additive color mixing of these sub pixels.

Applicable planar arrays include a stripe array, a square array, a delta array, and a Bayer array. Disposing the main pixels in a matrix leads to the achievement of a display apparatus having a large number of pixels.

Like the microlens 106, the color filters 109a to 109c are also disposed to be deviated from the center of the light-emitting region 108b. In this case, a color filter 109b may be disposed on a line connecting the apex B of the microlens 106 and the edge B′ of the light-emitting region on a side with the first light-emitting element.

The color filter 109b is disposed on a line connecting the edge C of the microlens 106 and the edge C′ of the light-emitting region. At least two different color filters may be disposed on a line segment connecting the apex of the microlens 106 right above the light-emitting region 108b and a light-emitting region adjacent to the light-emitting region 108b. The light emission from the adjacent light-emitting region is intended to reduce the light emission from an unintended microlens.

The light emitted from the light-emitting region 108b passes through the color filter 109b and is bent in an oblique direction by the microlens 106. Since the light does not pass through the color filters 109a and 109c of other sub pixels, the color purity can be increased.

As another exemplary embodiment, the following components may be added.

The light-emitting apparatus according to the present embodiment includes the first and the second light-emitting elements as blue-light-emitting elements, and further includes a fifth light-emitting element and a sixth light-emitting element disposed next to the first light-emitting element, a fifth optical member for receiving incident light emitted from the fifth light-emitting element, and a sixth optical member for receiving incident light emitted from the sixth light-emitting element. The fifth and the sixth light-emitting elements are green-light-emitting elements. In a direction parallel to the main surface, a distance between the midpoint of the light-emitting region of the sixth light-emitting element and the midpoint of the sixth optical member is larger than a distance between the midpoint of the light-emitting region of the fifth light-emitting element and the midpoint of the fifth optical member. A difference between a distance between the midpoint of the light-emitting region of the second light-emitting element and the apex of the second lens and the distance between the midpoint of the light-emitting region of the first light-emitting element and the apex of the first lens may be configured to be larger than a difference between a distance between the midpoint of the light-emitting region of the sixth light-emitting element and the apex of a sixth lens and the distance between the center of the light-emitting region of the fifth light-emitting element and the apex of a fifth lens. With the above-described configuration, blue light is efficiently extracted. Since blue light has a low relative luminosity, extracting blue light with a high efficiency is desirable.

Alternatively, in the direction parallel to the main subject, a distance between the midpoint of the light-emitting region of the sixth light-emitting element and the midpoint of the sixth optical member is larger than the distance between the midpoint of the light-emitting region of the fifth light-emitting element and the midpoint of the fifth optical member, and a difference between a distance between the midpoint of the light-emitting region of the second light-emitting element and the apex of the second lens and a distance between the midpoint of the light-emitting region of the first light-emitting element and the apex of the first lens may be configured to be smaller than a difference between a distance between the midpoint of the light-emitting region of the sixth light-emitting element and the apex of the sixth lens and a distance between the midpoint of the light-emitting region of the fifth light-emitting element and the apex of the fifth lens. With the above-described configuration, green light is efficiently extracted. Since green light has a high relative luminosity, extracting green light with a high efficiency is desirable.

As for the size of the light-emitting region, a difference in size between the light-emitting region of the sixth light-emitting element and the light-emitting region of the fifth light-emitting element may be configured to be larger than a difference in size between the light-emitting region of the second light-emitting element and the light-emitting region of the first light-emitting element. With the above-described configuration, green light is efficiently extracted. Since green light has a high relative luminosity, extracting green light with a high efficiency is desirable.

As for the size of the light-emitting region, the difference in size between the light-emitting region of the sixth light-emitting element and the light-emitting region of the fifth light-emitting element may be configured to be smaller than the difference in size between the light-emitting region of the second light-emitting element and the light-emitting region of the first light-emitting element. With the above-described configuration, blue light is efficiently extracted. Since blue light has a low relative luminosity, extracting blue light with a high efficiency is desirable.

The fifth and the sixth light-emitting elements may contain a phosphorescence light-emitting material. The first and the second light-emitting elements may contain a luminescence material or a thermal activation delayed fluorescence material.

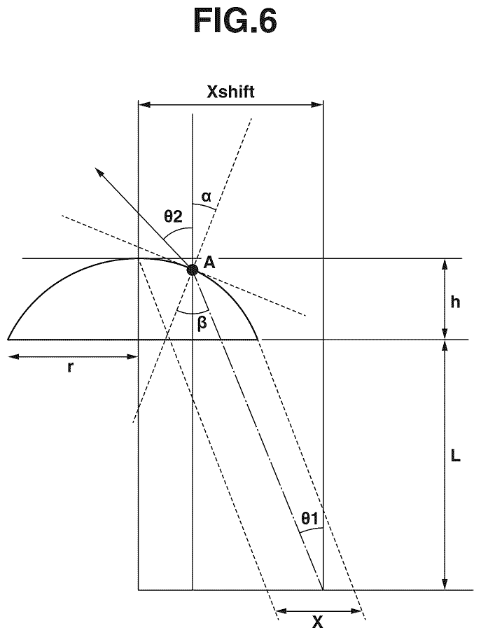

FIG. 6 is a cross-sectional view illustrating a relationship between a light-emitting region 108 and a microlens 106. FIG. 6 illustrates the microlens 106 having a height h, a radius r, and a refractive index n.

Light is emitted with an angle θ1 from the light-emitting region 108 and is bent with an angle θ2 at a point A of the microlens 106. The inclination with respect to the tangent line of the microlens 106 at the point A is an angle α. With the Snell's law, the following formula (1) is satisfied. In FIG. 6, α+θ1 is described as β.

$$1 \times sin ( θ2 + α ) = n \times sin ( α + θ1 ) \qquad ( 1 )$$

When formula (1) is solved for θ1, θ1 is represented by formula (2).

$$θ1 = {sin}^{- 1} \{ sin ( θ2 + α ) / n \} - α \qquad ( 2 )$$

When Xshift is the deviation from the apex of the microlens 106 and the center of the light-emitting region 108, and L is the distance from the light-emitting region 108 to the microlens 106, the size X of a light-emitting region 108 is represented by the following formula (3).

$$X = r - h \times tan ( θ1 ) \qquad ( 3 )$$

From formulas (3) and (2), the size X of the light-emitting region 108 is represented by formula (4).

$$X = r - h \times tan [ {sin}^{- 1} \{ sin ( θ2 + α ) / n \} - α ] \qquad ( 4 )$$

The relationship between the angle θ1 of the light emitted from the light-emitting region 108 and the deviation Xshift from the apex of the microlens 106 and the center of the light-emitting region 108 is represented by formula (5).

$${tan}^{- 1} ( Xshift / h + L ) > θ1 \qquad ( 5 )$$

A calculation based on a wave optics simulation gives results as illustrated in Table 1 of the deviation from the apex of the microlens 106 and the center of the light-emitting region 108 and the aperture ratio of the light-emitting region 108. However, due to other members such as the protective layer 104 and the color filters 109 existing between the microlens 106 and the light-emitting region 108, an error may be produced.

TABLE 1

| Distance between apex of microlens | Aperture ratio of |
|---|---|
| and center of light-emitting region | light-emitting region |
| 0.0 μm | 33% |
| 0.5 μm | 40% |
| 1.0 μm | 46% |
| 1.5 μm | 50% |

### [Other Components in Exemplary Embodiment]

### (Substrate)

The substrate 100 can be formed of any material as long as the substrate 100 supports the lower electrodes 101, the function layer 102, and the upper electrode 103, and examples of such material include glass, plastic, and silicon. Plastic may have flexibility. Examples of materials of the flexible substrate 100 include resins and organic materials, more specifically, polyimide resins, poly acrylic resins, and polymenthyl methacrylate (PMMA). Switching elements such as transistors, wirings, and interlayer insulators (not illustrated) may be formed on the substrate 100.

### (Lower Electrode)

The lower electrode 101 may be made of a metal material having a visible light reflectance of 50% or higher from the viewpoint of the light-emitting efficiency. Specific examples of usable metal materials include metals such as Al and Ag, and alloys of these metals with additives such as Si, Cu, Ni, Nd, and Ti. Also, the reflection electrode may have a barrier layer on the surface on the light-emitting side. Examples of preferable materials of the barrier layer include metals such as Ti, W, Mo, and Au, alloys of these metals, and transparent conductive oxides such as TIO and IZO. The lower electrode 101 may be an anode, and, in this case, the upper electrode 103 may be a cathode. In a case where the lower electrode 101 is a cathode, the upper electrode 103 may be an anode.

Although, in the above-described case, the lower electrode 101 is a reflection electrode and the upper electrode 103 is a light extraction electrode, the lower electrode 101 may be a light extraction electrode. In a case where the lower electrode 101 is a light extraction electrode, the lower electrode 101 has translucency like the upper electrode 103 (described below). Whether an electrode is the lower electrode 101 or the upper electrode 103 is defined by the distance to the substrate 100. The electrode closer to the substrate 100 having transistors for controlling the light emission is the lower electrode 101.

### (Insulating Layer)

The insulating layer 107 is disposed to cover the edges of the lower electrode 101, and an opening is formed so that the lower electrode 101 is partially exposed. The opening may be referred to as the light-emitting region 108. The insulating layer 107 is formed of an inorganic material such as a silicon nitride (SiN), a silicon oxynitride (SiON), and a silicon oxide (SiO). The insulating layer 107 is also referred to as a pixel separation film or bank.

The insulating layer 107 can be formed by using a known technique such as the sputtering method and the chemical vapor deposition method (CVD method). The insulating layer 107 can also be formed by using organic materials such as acrylic resins and polyimide resins.

### (Function Layer)

The function layer 102 having a light-emitting layer is disposed on the lower electrodes 101. The function layer 102 can be formed by using a known technique such as the evaporation method and the spin coat method.

The function layer 102 may include a plurality of layers and may be a stacked body formed of a plurality of layers, for example. The plurality of layers includes a hole injection layer, a hole transport layer, an electron blocking layer, a light-emitting layer, a hole blocking layer, an electron transport layer, and an electron injection layer. Other layers such as an electric charge generation layer and an electron blocking layer may be disposed between the above-described layers.

When holes injected from the anode and electrons injected from the cathode recombine in the light-emitting layer, light is emitted. The function layer 102 may be either an organic layer or an inorganic layer.

The light-emitting layer may include a plurality of layers or only one layer. In a case where the light-emitting layer includes a plurality of layers, any of the plurality of layers in the light-emitting layers may contain a red-light-emitting material, a green-light-emitting material, or a blue-light-emitting material. White light may be obtained by mixing the three different light-emitting colors enables. Any of organic layers may contain light-emitting materials of complementary colors such as a blue-light-emitting material and a yellow-light-emitting material.

Light-emitting materials may be materials composed of organic compounds or materials composed of quantum dots. In a case of using organic compounds, the light-emitting layer may include a first material and a second material. The first material emits main light and may be referred to as a dopant or guest. The second material has a larger weight ratio in the light-emitting layer than a weight ratio of the first material and may be referred to as a host. Examples of the first material include a material having a fluoranthene frame, a material having a pyrene frame, a material having a chrysene frame, and a material having an anthracene frame. A material having an anthracene frame has an anthracene structure in its structure and may be also referred to as an anthracene derivative.

The function layer 102 may be shared by a plurality of pixels. In this case, the light-emitting apparatus has a plurality of lower electrodes and one function layer. However, the present invention is not limited thereto. Whole or part of the function layer 102 may be formed by patterning for each individual pixel.

### (Upper Electrode)

The upper electrode 103 is disposed above the function layer 102, and has transparency. The upper electrode 103 may be made of a translucent material having a property of transmitting part of the light having reached the surface of the upper electrode 103 and reflecting other part of the light (this property is referred to as a translucent reflection property). Examples of component materials of the upper electrode 103 include transparent materials such as a transparent conductive oxide, simplex metals such as aluminum, silver, and gold, alkali metals such as lithium and cesium, alkaline-earth metals such as magnesium, calcium, and barium, and translucent materials composed of alloy materials containing these metal materials.

It is desirable that translucent materials be alloys primarily composed of magnesium and silver. As long as the upper electrode 103 has desired transmissivity, the upper electrode 103 may have a stacked structure made of the above-described materials. The upper electrode 103 may be disposed across a plurality of pixels.

While, in the above-described example, the upper electrode 103 is a light extraction electrode, the upper electrode 103 may be a reflection electrode. In this case, the upper electrode 103 may have a reflection property and be formed by using the materials described above as materials of the lower electrode 101.

The cathode is not particularly limited and may be a top-emission element using an oxide conductive layer made of an indium tin oxide (ITO) or a bottom-emission element using a reflection electrode such as aluminum (Al). The cathode forming method is not particularly limited. Using a direct-current (DC) or alternating-current (AC) sputtering method is more preferable since this method provides a favorable film coverage and makes it easier to lower the resistance.

### (Protective Layer)

The protective layer 104 is formed to cover the light-emitting element and has translucency. It is desirable that the protective layer 104 contain an inorganic material having low permeability for oxygen and moisture from outside. Specific examples of inorganic materials include a silicon nitride (e.g., SiN), a silicon oxynitride (e.g., SiON), a silicon oxide (SiOₓ), an aluminum oxide (e.g., Al₂O₃), and a titanium oxide (e.g., TiO₂). In the aspect of the protection performance, inorganic materials such as SiN, SiON, Al₂O₃ are desirable. The chemical vapor deposition method (CVD method), the atomic layer deposition method (ALD method), and the sputtering method may be used to form the protective layer 104. The protective layer 104 has either a monolayer structure or a stacked structure combining the above-described materials and formation methods as long as sufficient moisture blocking performance is obtained. Examples of applicable structures also include a stacked structure combining a layer formed by the ALD method and a layer formed by the sputtering method. A layer formed by the CVD method, a layer formed by the ALD method, and a layer formed by the CVD method may be disposed in this order. The protective layer 104 may be disposed across a plurality of pixels.

### (Flattening Layer)

The flattening layer 105 is disposed on the protective layer 104. The flattening layer 105 may be formed of a material having translucency which may be an inorganic or organic material. The flattening layer 105 reduces the unevenness of the protective layer 104. The flattening layer 105 does not need to be disposed in a case where the protective layer 104 having small unevenness is flattened by griding the protective layer 104.

The flattening layer 105 may have a lower refractive index than the protective layer 104. More specifically, the refractive index of the flattening layer 105 may be lower than the refractive index of the protective layer 104 and larger than 1.5. Further, the refractive index may be 1.5 or larger and 1.8 or less, and desirably is 1.5 or larger and 1.6 or less.

A layer disposed between the protective layer 104 and other members can be called as the flattening layer. Specific examples of materials of the flattening layer 105 include polyvinylcarbazole resins, polycarbonate resins, polyester resins, acrylonitrile butadiene styrene (ABS) resins, acrylic resins, polyimide resins, phenol resins, epoxy resins, silicone resins, and urea resins.

### (Optical Member)

The optical member (microlens 106) is formed on the flattening layer 105. The optical member may be a lens, more specifically, a microlens 106. The microlens 106 may be a lens having a small diameter. The microlens 106 can be formed in the exposure and development processes and may be formed by the reflow method, the area gradation method, and the etch back method. More specifically, a film (photoresist film) is formed by using the material for forming the microlens 106, and a photoresist film is exposed and developed by using a mask having continuous gradation variations. Examples of such masks include a gray mask or an area gradation mask. Using the area gradation mask leads to the achievement of light emission having a continuous gradation on the image forming surface by changing the density distribution of dots formed of a shading film having a resolution equal to or less than that of the exposure apparatus.

Etch back is performed on the microlens 106 formed by the exposure and development processes, whereby the lens shape can be adjusted.

Further, patterning and reflowing is performed on a resin to melt and solidify the resin, whereby the microlens 106 can be formed by the surface tension. In a case where an organic layer is used as the function layer 102, the temperature of the reflow process is set to a predetermined temperature or lower. For example, the predetermined temperature is 120° C. or lower.

In this case, the microlens 106 may be not only a spherical microlens but also an aspherical microlens, an asymmetry microlens, or a digital microlens.

### (Color Filters)

The color filters 109 may be disposed on the protective layer 104. For example, the color filters 109 factoring in the sizes of light-emitting elements may be disposed on another substrate, and the color filters 109 on another substrate may be stacked on the substrate in which light-emitting elements are disposed. Alternatively, color filters may be patterned on the above-described protective layer 104 by using the photolithography technique. Color filters may be made of macromolecules. Typically, color filters may be filters that transmit red, green, and blue light. More specifically, two or more color filters of which the first and the second color filters transmit light having wavelengths different from each other may be disposed. A third color filter that transmits light having a wavelength different from the wavelengths of the first and the second color filters may be disposed.

In a case where color filters are disposed, flattening layers may be disposed above and below the color filters, and the flattening layers may be made of the same material or different materials. Specific examples of materials of the flattening layer include polyvinylcarbazole resins, polycarbonate resins, polyester resins, ABS resins, acrylic resins, polyimide resins, phenol resins, epoxy resins, silicone resins, and urea resins.

### (Counter Substrate)

A counter substrate may be disposed on the above-described members. The counter substrate is a substrate disposed at a position facing the above-described substrate and thus referred to as the counter substrate. The counter substrate may be made of the same material as the above-described substrate. When the above-described substrate is referred to as a first substrate, the counter substrate may be referred to as a second substrate.

The light-emitting apparatus according to the above-described exemplary embodiment may be an organic light-emitting apparatus including an organic compound layer as the function layer 102.

### (Drive Circuit)

The light-emitting apparatus may have a drive circuit. The drive circuit may be of an active matrix type that independently controls light emission of the first and the second light-emitting elements. A circuit of the active matrix type may be based on voltage programming or current programming. The drive circuit has a pixel circuit for each pixel. The pixel circuit may include a light-emitting element, a transistor for controlling the light emission luminance of the light-emitting element, a transistor for controlling the light emission timing, a capacitance for holding the gate voltage of the transistor for controlling the light emission luminance, and a transistor for connecting to the ground (GND) without interposing the light-emitting element.

The magnitude of the drive current may be determined according to the size of the light-emitting region. More specifically, in a case where the first and the second light-emitting elements emit light with the same luminance, the current value applied to the first light-emitting element may be smaller than the current value applied to the second light-emitting element. Since the first light-emitting element has a smaller light-emitting region, the first light-emitting element may require a smaller current.

### [Applications of Light-Emitting Apparatus According to Exemplary Embodiment of Present Invention]

The light-emitting apparatus according to an exemplary embodiment of the present invention can be used as a component of display apparatuses and illumination apparatuses. Other applications of the light-emitting apparatus include an exposure light source of an electrophotographic image forming apparatus, a back light of a liquid crystal display apparatus, and a light-emitting apparatus having color filters in a white light source.

A display apparatus may be an image information processing apparatus including an image input unit for inputting image information from an area charge coupled device (CCD), a linear CCD, and a memory card, and an information processing unit for processing the input information, and displaying the input image on a display unit.

A display unit included in imaging apparatuses and ink jet printers may have a touch panel function. The method for driving the touch panel function is not particularly limited but may be an infrared method, a capacitance method, a resistance film method, and an electromagnetic induction method. A display apparatus may be used for the display unit of a multifunction printer.

A display apparatus according to the present exemplary embodiment will be described below with reference to the accompanying drawings.

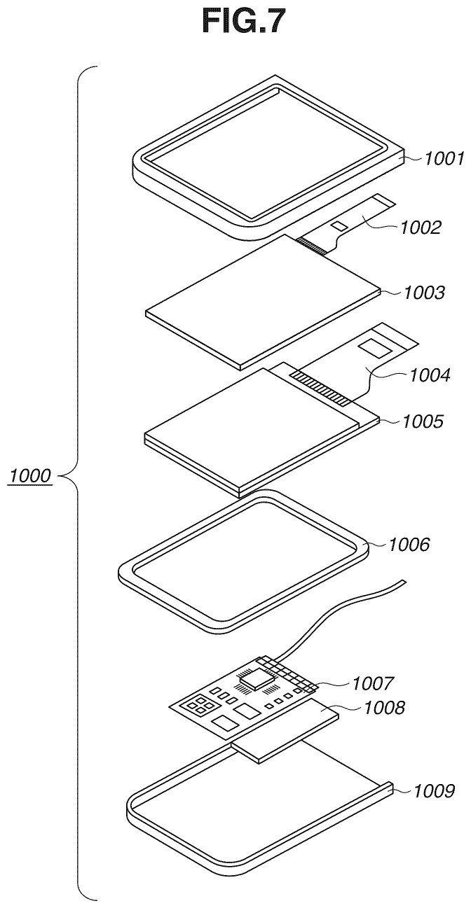

FIG. 7 schematically illustrates an example of a display apparatus 1000 according to the present exemplary embodiment. The display apparatus 1000 may include a touch panel 1003, a display panel 1005, a frame 1006, a circuit substrate 1007, and a battery 1008 between a top cover 1001 and a bottom cover 1009. The touch panel 1003 and the display panel 1005 are connected with flexible printed circuits (FPCs) 1002 and 1004, respectively. Transistors are mounted on the circuit substrate 1007. The battery 1008 may be omitted in a case where the display apparatus 1000 is not a portable apparatus. Even in a case where the display apparatus 1000 is a portable apparatus, the battery 1008 may be disposed at another position. The transistors may configure a control unit for controlling display of the display apparatus. The control unit can use a known method using a central processing unit (CPU). More specifically, the display apparatus 1000 according to the present exemplary embodiment includes a light-emitting apparatus and a control unit for controlling display of the light-emitting apparatus.

The display apparatus 1000 according to the present exemplary embodiment may include color filters having red, green, and blue colors. The red, green, and blue color filters may be arranged in a delta array or a stripe array.

The display apparatus 1000 according to the present exemplary embodiment may be used for the display unit of portable terminals. In this case, the display apparatus 1000 may include both a display function and an operation function. Examples of portable terminals include a portable phone, such as a smart phone, a tablet personal computer (PC), and a head mount display. In a case where the display apparatus 1000 is used as a display apparatus, a magnification optical system may be used together.

The display apparatus 1000 according to the present exemplary embodiment may be used for the display unit of an imaging apparatus including an optical unit including a plurality of lenses and an image sensor for receiving light having passed through the optical unit. The imaging apparatus may include a display unit for displaying information captured by the image sensor. The display unit may be exposed outside the imaging apparatus or disposed inside the viewfinder. The imaging apparatus may be a digital camera or a digital video camera.

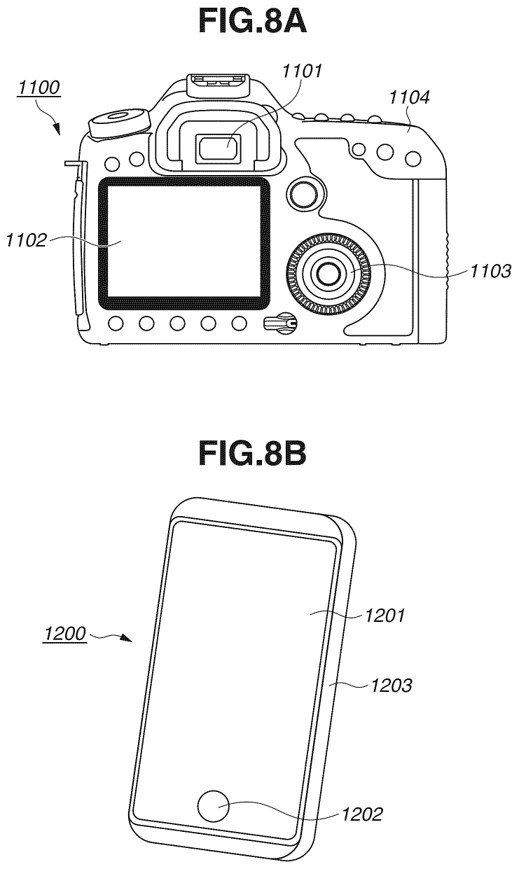

FIG. 8A schematically illustrates an example of an imaging apparatus 1100 according to the present exemplary embodiment. The imaging apparatus 1100 may include a viewfinder 1101, a back panel display 1102, an operation unit 1103, and a housing 1104. The viewfinder 1101 may include the display apparatus 1000 according to the present exemplary embodiment. In this case, the display apparatus 1000 may display not only captured images but also environmental information and imaging instructions. The environmental information includes the intensity of external light, the orientation of external light, the moving speed of a subject, and the possibility that the subject is shielded by a shielding.

Sine a timing suitable for imaging is a short time, information needs to be displayed as soon as possible. Therefore, among display apparatuses using the light-emitting apparatus according to an exemplary embodiment of the present invention, the display apparatus using an organic light-emitting element is desirable because of its high response speed. A display apparatus using an organic light-emitting element can be more suitably used for these apparatuses required for high display speeds than a liquid crystal display apparatus.

The imaging apparatus 1100 includes an optical unit (not illustrated). The optical unit including a plurality of lenses forms an image on the image sensor disposed in the housing 1104. Adjusting the relative positions of the plurality of lenses enables the focus adjustment. This operation can also be automatically performed. The imaging apparatus 1100 may also be called a photoelectric conversion apparatus. The photoelectric conversion apparatus may have an imaging method such as a method for detecting a difference from the previous image and a method for clipping an image from constantly recorded images, instead of performing successive image capturing.

FIG. 8B schematically illustrates an example of an electronic apparatus 1200 according to the present exemplary embodiment. The electronic apparatus 1200 includes a display unit 1201, an operation unit 1202, and a housing 1203. The housing 1203 may include a circuit, a printed circuit substrate having the circuit, a battery, and a communication unit. The operation unit 1202 may be a button or a touch-sensitive response unit. The operation unit 1202 may be a living body recognition unit for recognizing a fingerprint to unlock the operation unit 1202. The electronic apparatus 1200 including the communication unit may be considered as a communication apparatus. The electronic apparatus 1200 including a lens and an image sensor may be further have a camera function. An image captured by the camera function is displayed on the display unit 1201. Examples of the electronic apparatus 1200 includes a smart phone and a notebook personal computer.

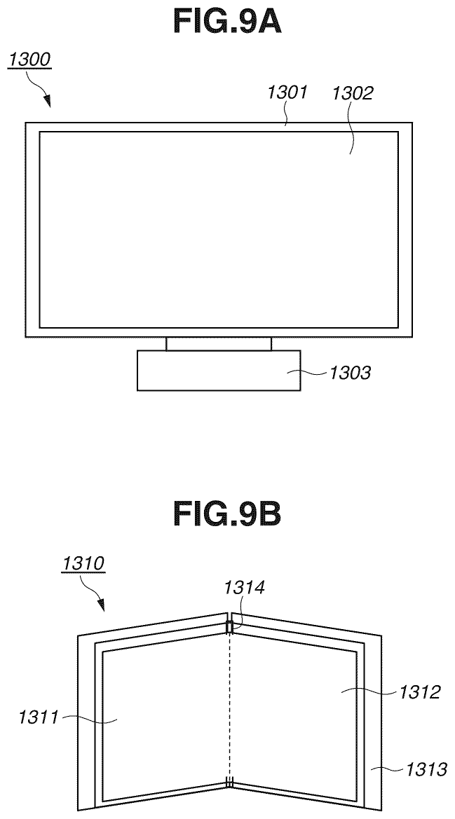

FIGS. 9A and 9B schematically illustrate examples of the display apparatus 1000 according to the present exemplary embodiment. FIG. 9A illustrates a display apparatus 1300, such as a television monitor and a personal computer (PC) monitor. The display apparatus 1300 includes a frame 1301 and a display unit 1302. The light-emitting apparatus according to the present exemplary embodiment may be used for the display unit 1302.

The display apparatus 1300 includes the frame 1301 and a base unit 1303 for supporting the display unit 1302. The base unit 1303 is not limited to the form illustrated in FIG. 9A. The bottom side of the frame 1301 may serve as the base unit 1303.

The frame 1301 and the display unit 1302 may be curved. The curvature radius may be 5,000 mm or more and 6000 mm or less.

FIG. 9B schematically illustrates another example of the display apparatus 1000 according to the present exemplary embodiment. In FIG. 9B, a display apparatus 1310 configured to be foldable is what is called a foldable display apparatus. The display apparatus 1310 includes a first display unit 1311, a second display unit 1312, a housing 1313, and a folding point 1314. The first display unit 1311 and the second display unit 1312 may include the light-emitting apparatus according to the present exemplary embodiment. The first display unit 1311 and the second display unit 1312 may be a single seamless display apparatus. The first display unit 1311 and the second display unit 1312 can be separated at the folding point 1314. The first display unit 1311 and the second display unit 1312 may display different images or display one image in combination.

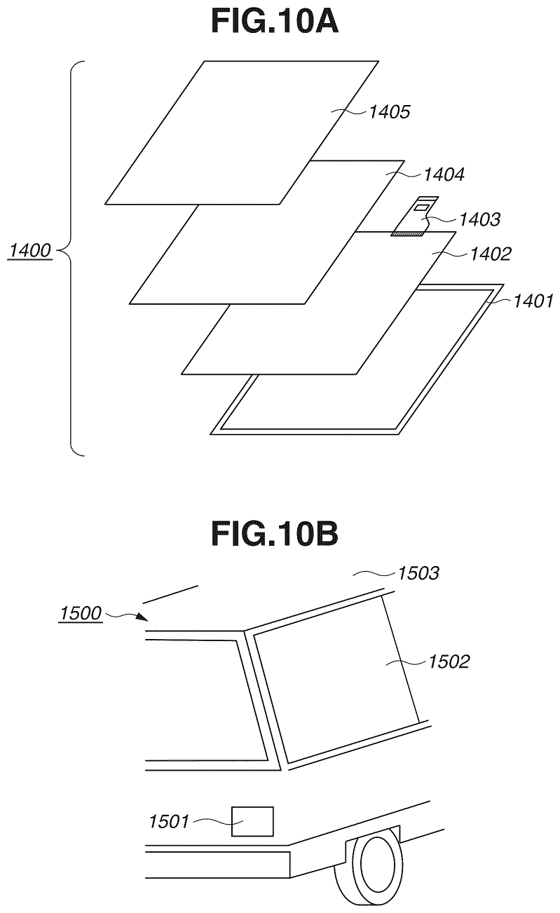

FIG. 10A schematically illustrates an example of an illumination apparatus 1400 according to the present exemplary embodiment. The illumination apparatus 1400 may include a housing 1401, a light source 1402, a circuit substrate 1403, an optical film 1404, and a light diffusion unit 1405. The light source 1402 may include the organic light-emitting element according to the present exemplary embodiment. The optical film 1404 may be filters for improving the color rendering. The light diffusion unit 1405 effectively diffuses light from the light source to deliver the light to a wide range, for example, in lighting up. The optical film 1404 and the light diffusion unit 1405 may be disposed on the illumination light emission side. A cover may be disposed on the most outer portion as required.

The illumination apparatus 1400 is, for example, an apparatus for illuminating a room. The illumination apparatus 1400 may emit white light, white daylight, and other light of any color ranging from blue to red. The illumination apparatus 1400 may include a light amount control circuit for controlling the light amount. The illumination apparatus 1400 may also include the organic light-emitting element of the present invention and a power source circuit connected to the organic light-emitting element. The power source circuit converts an AC voltage into a DC voltage. The color temperature of white is 4200K, and the color temperature of white daylight is 5000K. The illumination apparatus 1400 may include color filters.

The illumination apparatus 1400 according to the present exemplary embodiment may include a heat dissipation unit for discharging heat developed in the apparatus out of the apparatus. Examples of the heat dissipation unit include metals having high specific heat and liquid silicon.

FIG. 10B schematically illustrates an automobile 1500 as an example of a movable body according to the present exemplary embodiment. The automobile 1500 includes a rear light as an example of a lighting. The automobile 1500 may include a rear light 1501 that lights up when a brake operation is performed.

The rear light 1501 may include the organic light-emitting element according to the present exemplary embodiment. The rear light 1501 may include a protective member for protecting the organic EL element. The protective member may be made of any transparent material having a high strength to a certain extent. Desirably, the protective member is made of polycarbonate. A flange carboxylic acid derivative or an acrylonitrile derivative may be mixed with polycarbonate.

The automobile 1500 may include a car body 1503 and a window 1502 attached to the car body 1503. The window 1502 may be a transparent display in a case where the window 1502 is not a window for checking the front and back of the automobile. The transparent display may include the organic light-emitting element according to the present exemplary embodiment. In this case, electrodes and other component materials in the organic light-emitting element are transparent materials.

Examples of the movable body according to the present exemplary embodiment include a ship, an aircraft, and a drone. The movable body may include a main frame and a lighting attached to the main frame. The lighting may emit light to inform of the position of the main frame. The lighting includes the organic light-emitting element according to the present exemplary embodiment.

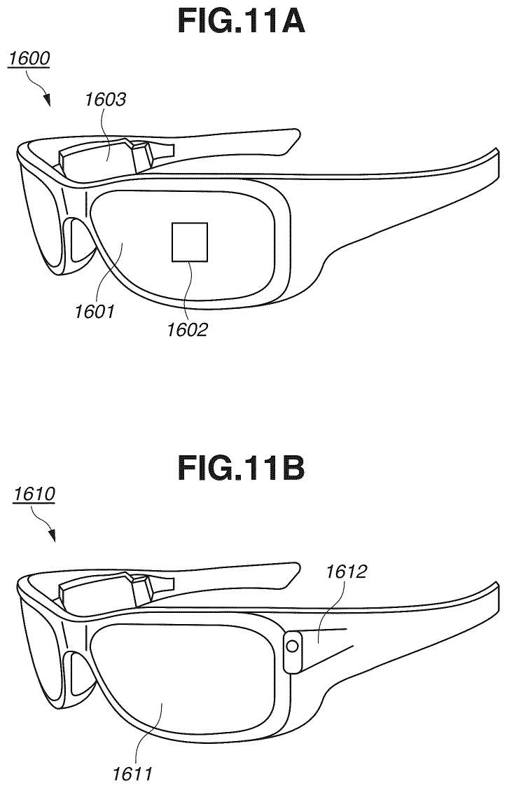

Examples of applications of the display apparatus according to each of the above-described exemplary embodiments will be described below with reference to FIGS. 11A and 11B. The display apparatus is applicable to a system wearable as a wearable device, such as smart glasses, a head mount display (HMD), and a smart contact lens. An imaging display apparatus that is used for such applications include an imaging apparatus capable of photoelectrically converting visible light, and a display apparatus capable of emitting visible light.

FIG. 11A illustrates glasses 1600 (smart glasses) according to an application example. The front side of a lens 1601 of the glasses 1600 includes an imaging apparatus 1602 such as a complementary metal oxide semiconductor (CMOS) sensor and a single photon avalanche diode (SPAD). The back side of the lens 1601 includes the display apparatus according to each of the above-described exemplary embodiments.

The glasses 1600 further includes a control apparatus 1603 that functions as a power source for supplying power to the imaging apparatus 1602 and the display apparatus according to each of the exemplary embodiments. The control apparatus 1603 controls operations of the imaging apparatus 1602 and the display apparatus. The lens 1601 includes an optical system for concentrating light on the imaging apparatus 1602.

FIG. 11B illustrates glasses 1610 (smart glasses) according to an application example. The glasses 1610 include a control apparatus 1612 that includes an imaging apparatus equivalent to the imaging apparatus 1602 and the display apparatus. The imaging apparatus in the control apparatus 1612 and an optical system for projecting the light emitted from the display apparatus are formed in a lens 1611. An image is projected on the lens 1611. The control apparatus 1612 functions as a power source for supplying power to the imaging apparatus and the display apparatus, and controls operations of the imaging apparatus and the display apparatus. The control apparatus 1612 may include a line-of-sight detection unit for detecting the line of sight of the user wearing the glasses 1610. Infrared radiation may be used to detect the line of sight. An infrared light emission unit emits infrared light to an eyeball of the user gazing a displayed image. When the imaging unit including a light detecting element detects reflected light from the eyeball out of the emitted infrared light, a captured image of the eyeball is obtained. A reduction unit for reducing light from the infrared light emission unit to the display unit in the planar view reduces the degradation of the image quality.

The line of sight of the user to the displayed image is detected from a captured image of the eyeball obtained through infrared image capturing. Any known technique is applicable to the line-of-sight detection using a captured image of the eyeball. Examples of applicable methods include a line-of-sight detection method based on a Purkinje image by the illumination light reflection in the cornea.

More specifically, line-of-sight detection processing is performed based on a pupillary cornea reflection method. The line of sight of the user is detected by using the pupillary cornea reflection method, more specifically, by deriving a line-of-sight vector representing an orientation (rotational angle) of the eyeball based a pupillary image and Purkinje image included in the captured image of the eyeball.

The display apparatus according to an exemplary embodiment of the present invention may include an imaging apparatus having light receiving elements and control the displayed image of the display apparatus based on user's line-of-sight information from the imaging apparatus.

More specifically, based on the line-of-sight information, the display apparatus determines a first visual field region gazed by the user and a second visual field region other than the first visual field region. The first and the second visual field regions may be determined by the control apparatus of the display apparatus. Alternatively, the first and the second visual field regions determined by an external control apparatus may be received. In the display region of the display apparatus, a display resolution of the first visual field region is controlled to be higher than a display resolution of the second visual field region. More specifically, the resolution of the second visual field region may be set lower than the resolution of the first visual field region.

The display region includes a first display region, and a second display region different from the first display region. The display region having a higher priority may be determined from the first and the second display regions based on the line-of-sight information. The first and the second visual field regions may be determined by the control apparatus of the display apparatus. Alternatively, the first and the second visual field regions determined by an external control apparatus may be received. A resolution of the high-priority region may be controlled to be higher than a resolution of regions other than high-priority region. More specifically, regions having a relatively low priority may have a low resolution.

An artificial intelligence (AI) may be used to determine the first visual field region and a high-priority region. An AI model may be configured to, by using teacher data, estimate the angle of the line of sight and the distance to an object existing ahead of the line of sight based on the eyeball image. The teacher data includes an eyeball image and the direction of the actual line of sight of the eyeball of the image. An AI program may be included in the display apparatus, the imaging apparatus, or an external apparatus. In a case where the external apparatus has the AI program, the external apparatus informs the display apparatus of the AI program.

In a case where display control is performed through visual recognition and detection, the present exemplary embodiment can be preferably applied to smart glasses further including an imaging apparatus for capturing an outside image. Smart glasses can display captured external information in real time.

As described above, using an apparatus including the organic light-emitting apparatus according to the present exemplary embodiment enables stable long-time display with a favorable image quality.

The present invention is not limited to the above-described exemplary embodiments, and various modifications and variations can be made without departing from the spirit and scope of the present invention. Accordingly, the following claims are appended to disclose the scope of the present invention.

The present invention provides a light-emitting apparatus for stabilizing the display quality regardless of the user's line-of-sight position even in a case where low power consumption is achieved by using lenses.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A light-emitting apparatus comprising:
a substrate having a main surface;
a first light-emitting element and a second light-emitting element disposed in the main surface;
a first lens configured to receive incident light emitted from the first light-emitting element; and
a second lens configured to receive incident light emitted from the second light-emitting element,
wherein the first light-emitting element and the second light-emitting element include a lower electrode, an upper electrode, a light-emitting layer disposed between the lower electrode and the upper electrode, and an insulating layer covering an edge of the lower electrode to define a light-emitting region,
wherein, in a direction parallel to the main surface, a distance between a midpoint of the light-emitting region of the second light-emitting element and an apex of the second lens is larger than a distance between a midpoint of the light-emitting region of the first light-emitting element and an apex of the first lens, and
wherein the light-emitting region of the second light-emitting element is larger than the light-emitting region of the first light-emitting element.

2. The light-emitting apparatus according to claim 1, further comprising:
a third light-emitting element; and
a third lens configured to receive incident light emitted from the third light-emitting element,
wherein, in a direction parallel to the main surface, a distance between a midpoint of the light-emitting region of the third light-emitting element and an apex of the third lens is larger than the distance between the midpoint of the light-emitting region of the second light-emitting element and the apex of the second lens, and
wherein the light-emitting region of the third light-emitting element is larger than the light-emitting region of the second light-emitting element.

3. The light-emitting apparatus according to claim 1,
wherein the first light-emitting element includes a lower electrode, a light-emitting layer, and an upper electrode, in this order, and a first insulating layer and a second insulating layer covering respective edges of the lower electrode, and
wherein the midpoint of the light-emitting region of the first light-emitting element is the midpoint of a line segment connecting an edge of the first insulating layer and an edge of the second insulating layer.

4. The light-emitting apparatus according to claim 1, wherein the first lens and the second lens are disposed at a position closer to a light extraction side of the light-emitting apparatus than the first light-emitting element and the second light-emitting element, respectively.

5. The light-emitting apparatus according to claim 1,
wherein the light-emitting region of the light-emitting apparatus includes a first light-emitting region including a center of the light-emitting region in a planar view, and includes a second light-emitting region surrounding the first light-emitting region in a planar view, and
wherein the first light-emitting element is disposed in the first light-emitting region, and the second light-emitting element is disposed in the second light-emitting region.

6. The light-emitting apparatus according to claim 1,
wherein each of the light-emitting regions of the first light-emitting element and the second light-emitting element is a polygon, and
wherein, at least one side of the polygon of the light-emitting region of the first light-emitting element lie inside the polygon of the light-emitting region compared to a side of the polygon of the light-emitting region of the second light-emitting element.

7. The light-emitting apparatus according to claim 6,
wherein, in the light-emitting region of the first light-emitting element, sides lying inside the polygon of the light-emitting region of the first light-emitting element compared to sides of the polygon of the light-emitting region of the second light-emitting element are two, and
wherein the two sides are most separated from each other among sides of the polygon.

8. The light-emitting apparatus according to claim 6,
wherein the first light-emitting element is included in the first light-emitting region of the light-emitting apparatus, and the second light-emitting element is included in the second light-emitting region surrounding the first light-emitting region,
wherein, in the light-emitting region of the second light-emitting element, a side lying inside the polygon of the light-emitting region of the first light-emitting element is one side of the polygon of the light-emitting region of the second light-emitting element, and
wherein the one side is a closest side to the first light-emitting region among sides of the polygon.

9. The light-emitting apparatus according to claim 1,
wherein the light-emitting region of the light-emitting apparatus includes the first light-emitting region including a center of the light-emitting region in a planar view, and includes the second light-emitting region surrounding the first light-emitting region in a planar view,
wherein the first light-emitting element is disposed in the first light-emitting region, and the second light-emitting element is disposed in the second light-emitting region,
wherein the light-emitting apparatus further includes a second color filter configured to receive incident light emitted from the second light-emitting element, a fourth light-emitting element disposed next to the second light-emitting element, and a fourth color filter configured to receive incident light emitted from the fourth light-emitting element and transmit light having a wavelength different from the second color filter, and
wherein the second color filter and the fourth color filter are disposed on a line segment connecting an edge of the second lens on a side with the first light-emitting element and an edge of the light-emitting region of the fourth light-emitting element on a side with the first light-emitting element.

10. The light-emitting apparatus according to claim 1, wherein a width of the second light-emitting region is represented by the following formula:
$$X = r - h \times tan [ {sin}^{- 1} \{ sin ( θ2 + α ) / n \} - α ] {tan}^{- 1} ( Xshift / h + L ) > θ1$$
where h, r, and n denotes a height, a radius, and a refractive index of the second lens, respectively, θ1 denotes an angle of light emitted from the second light-emitting region, a denotes an angle of the second lens of at a point where the light emitted from the second light-emitting region is bent by the second lens, θ2 denotes an angle of the bent light, Xshift denotes an amount of deviation from the apex of the second lens and the midpoint of the second light-emitting region, and L denotes a distance from the second light-emitting region to the second lens.

11. A light-emitting apparatus comprising:
a substrate having a main surface;
a first light-emitting region including a first light-emitting element disposed in the main surface; and
a second light-emitting element disposed in the main surface,
wherein the first light-emitting region includes a center of a light-emitting element group in a planar view,
wherein the second light-emitting region surrounds the first light-emitting region,
wherein the first light-emitting element and the second light-emitting element include a lower electrode, an upper electrode, a light-emitting layer disposed between the lower electrode and the upper electrode, and an insulating layer covering an edge of the lower electrode to define a light-emitting region, and
wherein the light-emitting region of the second light-emitting element is larger than the light-emitting region of the first light-emitting element.

12. The light-emitting apparatus according to claim 11, wherein the first light-emitting element and the second light-emitting element emit light of a same color.

13. The light-emitting apparatus according to claim 11,
wherein the first light-emitting element and the second light-emitting element include a first electrode, a second electrode, an organic compound layer disposed between the first and the second electrodes, a first insulating layer in contact with an edge of the first electrode; and a second insulating layer in contact with an other edge of the first electrode,
wherein, in a cross-section perpendicular to the main surface of the substrate, a distance between the first insulating layer and the second insulating layer serves as the light-emitting region.

14. The light-emitting apparatus according to claim 11, further comprising:
a first lens configured to receive incident light emitted from the first light-emitting element; and
a second lens configured to receive incident light emitted from the second light-emitting element,
wherein, in a direction parallel to the main surface, a distance between a midpoint of the light-emitting region of the second light-emitting element and an apex of the second lens is larger than a distance between a midpoint of the light-emitting region of the first light-emitting element and an apex of the first lens.

15. The light-emitting apparatus according to claim 11, wherein the first lens and the second lens are disposed at positions closer to a light extraction side of the light-emitting apparatus than the first second light-emitting element and the second light-emitting element.

16. A light-emitting apparatus comprising:
a substrate having a main surface;
a first region disposed in the main surface and configured to include a center of the light-emitting region in a planar view;
a second region disposed in the main surface and configured to be in contact with the first region in a planar view;
a first light-emitting element included in the first region; and
a second light-emitting element included in the second region,
wherein the first light-emitting element and the second light-emitting element include a lower electrode, an upper electrode, a light-emitting layer disposed between the lower electrode and the upper electrode, and an insulating layer covering an edge of the lower electrode to define a light-emitting region, and
wherein the light-emitting region of the second light-emitting element is larger than the light-emitting region of the first light-emitting element.

17. The light-emitting apparatus according to claim 16, comprising:
a first lens configured to receive incident light emitted from the first light-emitting element; and
a second lens configured to receive incident light emitted from the second light-emitting element,
wherein, in a direction parallel to the main surface, a distance between a midpoint of the light-emitting region of the second light-emitting element and a midpoint of the second lens is larger than a distance between a midpoint of the light-emitting region of the first light-emitting element and a midpoint of the first lens.

18. The light-emitting apparatus according to claim 1, wherein the light-emitting apparatus is of an active matrix type that independently controls light emission of the first light-emitting element and the second light-emitting element.

19. The light-emitting apparatus according to claim 1,
wherein the first light-emitting element and the second light-emitting element are blue-light-emitting elements,
wherein the light-emitting apparatus further includes a fifth light-emitting element and a sixth light-emitting element disposed next to the first light-emitting element, a fifth lens configured to receive incident light emitted from the fifth light-emitting element, and a sixth lens configured to receive incident light emitted from the sixth light-emitting element,
wherein the fifth light-emitting element and the sixth light-emitting element are green-light-emitting elements,
wherein, in a direction parallel to the main surface, a distance between a midpoint of the light-emitting region of the sixth light-emitting element and a midpoint of the sixth lens is larger than a distance between a midpoint of the light-emitting region of the fifth light-emitting element and a midpoint of the fifth lens, and
wherein a difference between the distance between the midpoint of the light-emitting region of the second light-emitting element and the apex of the second lens and the distance between the midpoint of the light-emitting region of the first light-emitting element and the apex of the first lens is larger than a difference between a distance between the midpoint of the light-emitting region of the sixth light-emitting element and an apex of the sixth lens and a distance between the midpoint of the light-emitting region of the fifth light-emitting element and an apex of the fifth lens.

20. The light-emitting apparatus according to claim 19, wherein a difference in size between the light-emitting region of the sixth light-emitting element and the light-emitting region of the fifth light-emitting element is larger than a difference in size between the light-emitting region of the second light-emitting element and the light-emitting region of the first light-emitting element.

21. The light-emitting apparatus according to claim 19, wherein the fifth light-emitting element and the sixth light-emitting element contain a phosphorescence light-emitting material.

22. A display apparatus comprising:
the light-emitting apparatus according to claim 1; and
a control unit configured to control display of the light-emitting apparatus.

23. An imaging apparatus comprising:
an optical unit including a plurality of lenses;
an image sensor configured to receive light having passed through the optical unit; and
a display unit configured to display an image captured by the image sensor,
wherein the display unit includes the light-emitting apparatus according to claim 1.

24. An electronic apparatus comprising:
a display unit including the light-emitting apparatus according to claim 1;
a housing in which the display unit is disposed; and
a communication unit disposed in the housing and configured to communicate with an external apparatus.

25. An illumination apparatus comprising:
a light source including the light-emitting apparatus according to claim 1; and
a light diffusion unit or an optical film configured to transmit light emitted by the light source.

26. A movable body comprising:
a lighting including the light-emitting apparatus according to claim 1; and
a main frame in which the lighting is disposed.
